(19) United States
(12) Patent Application Publication
(10) Pub. No.: US 2012/0138336 A1
(43) Pub. Date: Jun. 7, 2012

(54) PRINTED CIRCUIT BOARD AND METHOD OF MANUFACTURING THE SAME

(75) Inventors: Ryoichi WATANABE, Gyunggi-do (KR); Going Sik KIM, Gyunggi-do (KR); Chang Sup RYU, Gyunggi-do (KR)

(73) Assignee: SAMSUNG ELECTRO-MECHANICS CO., LTD., Gyunggi-do (KR)

(21) Appl. No.: 13/091,074

(22) Filed: Apr. 20, 2011

(30) Foreign Application Priority Data
Dec. 6, 2010 (KR) 10-2010-0123705

(51) Int. Cl. H05K 1/02; B05D 5/12

(52) U.S. Cl. 174/250; 427/97.8

(57) ABSTRACT

Disclosed herein is a printed circuit board and a method of manufacturing the same, in which a circuit pattern one end of which is embedded in a trench and the other end of which protrudes from an insulating layer is formed, so that the circuit pattern is not easily separated from the insulating layer and the separation problems of the circuit pattern due to undercutting are solved. Also, the adhesion between the insulating layer and the circuit pattern is enhanced, more stably forming a fine circuit pattern. Even when a plating resist is formed thin, it is possible to form the circuit pattern, resulting in a high-solution circuit pattern.

### CROSS REFERENCE TO RELATED APPLICATION

This application claims the benefit of Korean Patent Application No. 10-2010-0123705, filed Dec. 6, 2010, entitled “Printed circuit board and method of manufacturing the same”, which is hereby incorporated by reference in its entirety into this application.

### BACKGROUND OF THE INVENTION

1. Technical Field

The present invention relates to a printed circuit board (PCB) and a method of manufacturing the same.

2. Description of the Related Art

Mobile electronic devices including mobile phones, digital cameras and so on have recently made progress. This progress has been accompanied by ongoing research and development into smaller, slimmer and multi-functionalized electronic devices. Such a trend is directly linked with the demand to reduce the size of a semiconductor package which forms the electronic device, and it is ultimately required to increase the density of a substrate of the semiconductor package. Such a high-density or high-integrated substrate is achieved by reducing the circuit width or circuit pitch. Recently a SAP (Semi-Additive Process) is known to be a process used to form a fine circuit pattern of the substrate.

Conventional SAP is performed as follows.

First, in order to form a circuit pattern on the surface of an insulating layer, electroless plating or sputtering is carried out thus forming a seed layer.

Next, a resist film is applied on the seed layer, and then patterned, thus forming a plating resist pattern. As such, transferring a pattern onto the resist film may be carried out by selectively applying UV light using an artwork film, and performing photo-exposure and developing which removes an uncured portion of the resist film using a developing solution.

Next, electroplating is performed using the seed layer as a lead wire, a circuit pattern is formed on the portion where the resist film was removed, and then the resist film is stripped off.

Next, a portion of the seed layer wherein the circuit pattern is not formed is removed using etching.

However, the circuit pattern resulting from such SAP has the following problems.

Specifically, the force of adhesion between the circuit pattern and the insulating layer becomes problematic. Because the circuit pattern having metallic properties and the insulating layer having insulating properties are formed of materials that are different from each other, the adhesion therebetween is limited. In particular, the circuit pattern maintains adhesion to the flat surface of the insulating layer with which it is in contact. However, when a fine circuit pattern is formed, the contact area between the circuit pattern and the insulating layer is remarkably reduced, unfortunately easily allowing the circuit pattern to separate from the surface of the insulating layer.

Furthermore, in the course of etching and removing the seed layer exposed from the circuit pattern formed using electroplating, undercut defects may occur in the circuit pattern. Such undercut defects may reduce the contact area between the circuit pattern and the insulating layer, making it easier to separate the fine circuit pattern from the insulating layer.

Furthermore, the resolution of the fine circuit pattern becomes problematic. Typically, a circuit pattern is formed on an open portion of a plating resist using plating. In order to prevent over-plating of the circuit pattern, the formation of the plating resist pattern thicker than the circuit pattern is inevitable. Whereas, in order to achieve a circuit pattern having high resolution, a plating resist pattern should be formed as thin as possible. Consequently, there occurs a contradiction between these two cases.

### SUMMARY OF THE INVENTION

Accordingly, the present invention has been made keeping in mind the problems encountered in the related art and the present invention is intended to provide a PCB and a method of manufacturing the same, in which the contact area between a circuit pattern and an insulating layer may be increased thus solving separation problems of the circuit pattern, minimizing damage to the circuit pattern due to undercutting, and achieving a fine circuit pattern.

An aspect of the present invention provides a PCB, including an insulating layer having a trench formed in a negative shape, and a circuit pattern formed on the trench so that one end of the circuit pattern is embedded in the trench and the other end thereof is formed to protrude from the insulating layer.

In this aspect, a seed layer may be further provided between the insulating layer and the circuit pattern.

In this aspect, the trench may have a tapered inner wall.

In this aspect, the trench may include at least two continuously formed rectangular grooves.

In this aspect, the trench may include at least two continuously formed inverted triangular grooves.

In this aspect, the trench may include a first groove and at least two continuously formed rectangular second grooves on a bottom surface of the first groove.

In this aspect, the trench may include a first groove and at least two continuously formed inverted triangular second grooves on a bottom surface of the first groove.

Another aspect of the present invention provides a method of manufacturing a PCB, including (A) forming a trench in a negative shape on an insulating layer, (B) applying a resist film on the insulating layer, and patterning the resist film to form an opening corresponding to the trench, thus forming a plating resist pattern, (C) plating the insulating layer, thus forming a circuit pattern one end of which is embedded in the trench and the other end of which protrudes from a surface of the insulating layer, and (D) removing the plating resist pattern.

In this aspect, the method may further include forming a seed layer on the insulating layer, between (A) and (B).

In this aspect, the method may further include (E) removing the seed layer exposed from the circuit pattern, after (D).

In this aspect, (A) may include forming a trench having a tapered inner wall on the insulating layer.

In this aspect, (A) may include forming a trench including at least two continuously formed rectangular grooves on the insulating layer.

In this aspect, (A) may include forming a trench including at least two continuously formed inverted triangular grooves on the insulating layer.

In this aspect, (A) may include forming a trench including a first groove and at least two continuously formed rectangular second grooves on a bottom surface of the first groove, on the insulating layer.

In this aspect, (A) may include forming a trench including a first groove and at least two continuously formed inverted triangular second grooves on a bottom surface of the first groove, on the insulating layer.

### BRIEF DESCRIPTION OF THE DRAWINGS

The features and advantages of the present invention will be more clearly understood from the following detailed description taken in conjunction with the accompanying drawings, in which:

FIGS. 1A to 1F are cross-sectional views showing a PCB according to an embodiment of the present invention; and

FIGS. 2A˜2F, 3 to 7 are cross-sectional views sequentially showing a process of manufacturing the PCB according to an embodiment of the present invention.

### DESCRIPTION OF SPECIFIC EMBODIMENTS

Hereinafter, embodiments of the present invention will be described in detail while referring to the accompanying drawings. Throughout the drawings, the same reference numerals are used to refer to the same or similar constituents. Furthermore, descriptions of known techniques, even if they are pertinent to the present invention, are regarded as unnecessary and may be omitted in so far as they would make the characteristics of the invention unclear.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

PCB

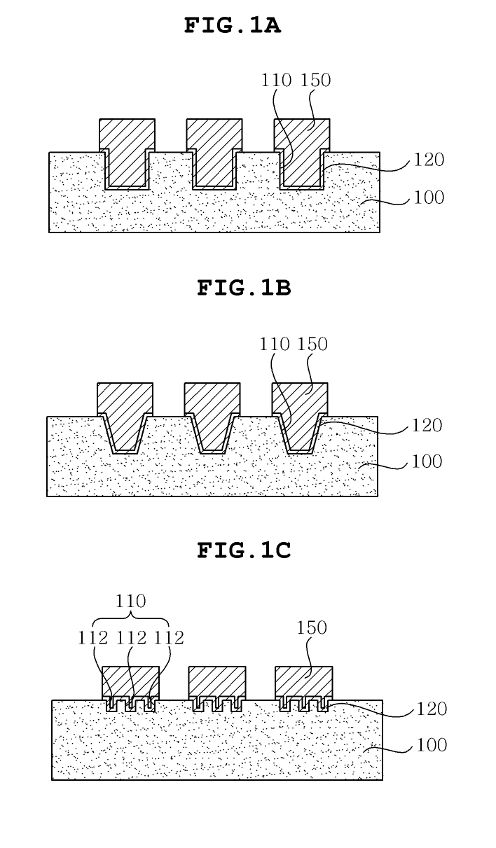

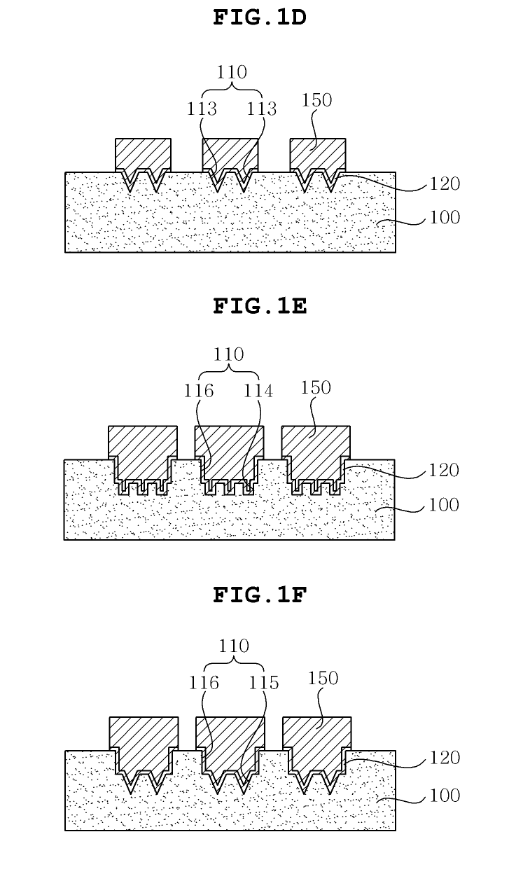

FIGS. 1A to 1F are cross-sectional views showing a PCB according to an embodiment of the present invention.

As shown in FIG. 1A, the PCB according to the present embodiment includes an insulating layer 100 having trenches 110 formed in a negative shape, and a circuit pattern 150 one end of which is embedded in each trench 110 and the other end of which is formed to protrude from the insulating layer 100. Also, a seed layer 120 may be further provided between the insulating layer 100 and the circuit pattern 150.

The insulating layer 100 may be formed of an insulating material typically used for a PCB, for example, a composite polymer resin such as a prepreg (PPG). In addition, an epoxy resin such as FR-4 BT or the like or ABF (Ajinomoto Build-up Film) may be included, and the material of the insulating layer is not particularly limited thereto. The trenches 110 are processed on the surface of the insulating layer 100. As such, a single insulating layer 100 may be used alone so that either or both surfaces thereof are processed to form trenches 110. Otherwise, an insulating layer 100 may be stacked on a base substrate having a circuit layer making it possible to form a multilayer structure.

The trenches 110 are formed in a negative shape at a predetermined depth from the surface of the insulating layer 100. The trenches 110 in which the circuit pattern 150 is embedded should be formed to have the same pattern as that of one end of the circuit pattern 150. Thus, in FIGS. 1A to 1F, even if the intervals between respective trenches 110 are seen to be the same, the present invention is not limited thereto, and the intervals between respective trenches 110 may vary depending on the shape of the circuit pattern 150 to be formed.

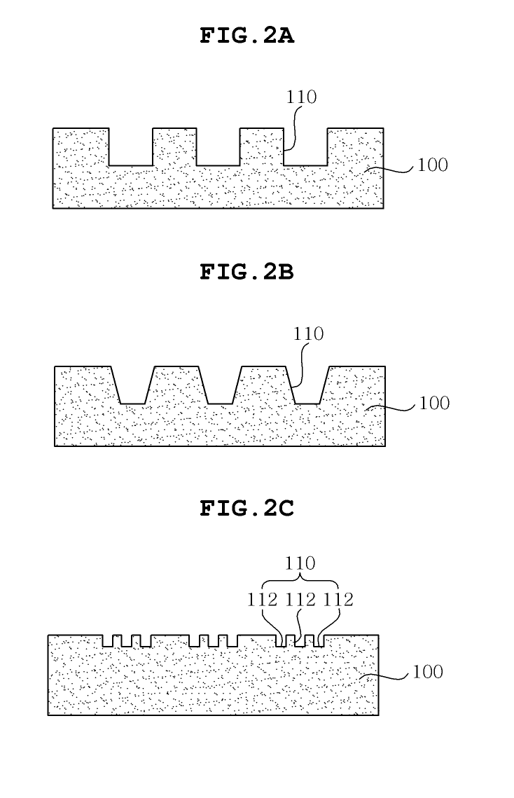

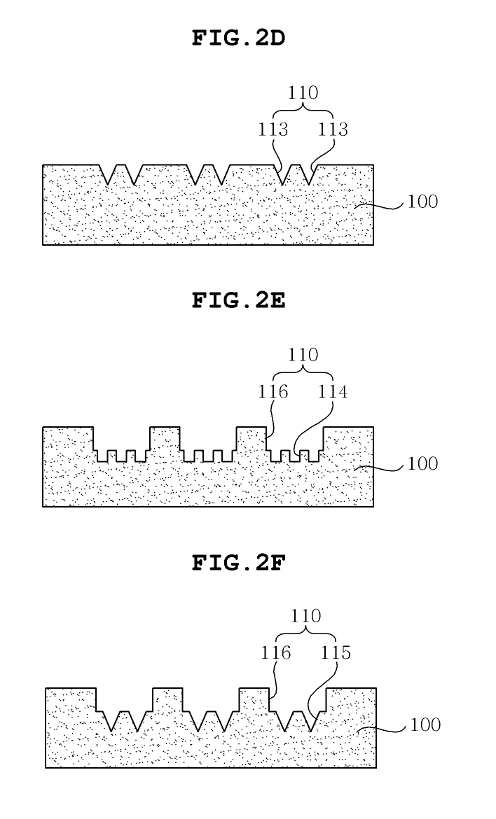

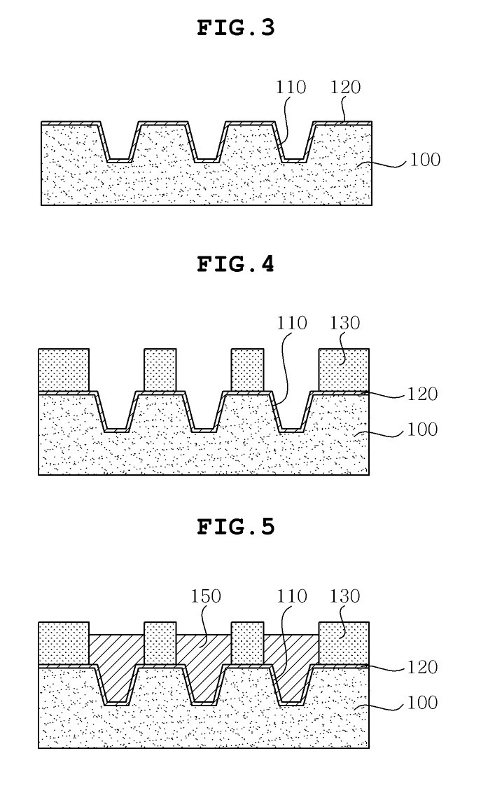

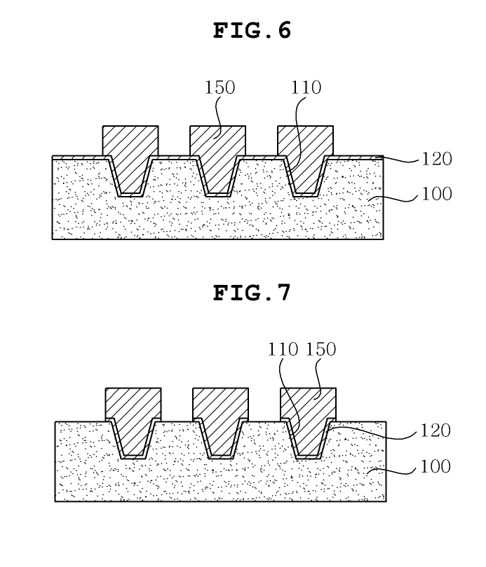

In the present invention, the reason why the trenches 110 are processed and one end of the circuit pattern 150 is embedded in the trenches 110 is that the contact area between the circuit pattern 150 and the insulating layer 100 is increased, thereby enhancing the adhesion therebetween. The structure of such trenches 110 may be variously modified. For example, a variety of modifications of the trenches 110 are illustrated in FIGS. 2B˜2F. In the detailed description of the present invention, in order to distinctly represent a unit of trenches 110 including at least two grooves 112, 113, 114, 115, 116, the terms grooves 112, 113, 114, 115, 116 and trenches 110 are separately used.

FIG. 2B shows the trenches 110 having a tapered inner wall. In the case where trenches 110 are typically formed using a laser, this may result in the trenches 110 shown in FIG. 2B.

FIG. 2C or 2D shows trenches 110 including at least two continuously formed rectangular grooves 112 (FIG. 2C) or continuously formed inverted triangular grooves 113 (FIG. 2D). Compared to FIG. 1A or 1B, the surface area of these trenches may be larger.

FIG. 2E or 2F shows trenches 110 including first grooves 116 and at least two continuously formed rectangular second grooves 114 (FIG. 2E) or continuously formed inverted triangular second grooves 115 (FIG. 2F) on the bottom surface of the first grooves 116. These trenches 110 have two-stage grooves, in which the first grooves 116 are processed at a predetermined width and depth so as to correspond to the circuit pattern 150 (FIG. 1E or 1F), and at least two second grooves 114, 115 smaller than the first grooves are further formed on the bottom surface of the first grooves 116.

The trenches 110 according to the present invention are a region in which one end of the circuit pattern 150 is embedded. In the present invention, when the trenches 110 are processed and the circuit pattern 150 is partially embedded therein, the contact area between the circuit pattern 150 and the insulating layer 100 may be increased, and the degree of damage done to the circuit pattern 150 due to undercut defects occurring in the course of etching and removing the seed layer 120 may be reduced. Specifically, a circuit structure which is partially embedded according to the present invention is different from a conventional circuit structure in which a circuit pattern 150 is completely embedded in an insulating layer 100. Thus, even when the trenches 110 are processed shallowly, the purpose of the present invention may be achieved. In the case where the trenches 110 are processed shallowly, the processing cost may be reduced, thereby increasing productivity. In particular, in the conventional structure in which the circuit pattern 150 is completely embedded in the insulating layer 100, the trenches 110 are required to be processed at a predetermined depth or more in order to embed the circuit. However, in the case where trenches 110 are processed on the insulating layer 100 using a laser, the wall of the insulating layer 100 is angled. Furthermore, as the depth is increased, the trenches are provided in the form of a V shape the width of which becomes decreased, and the depth of processable trenches 110 is thus confined. Also in the case where it is difficult to ensure the depth, the width of the trenches 110 cannot but increase, making it impossible to form a fine circuit. Hence, the trenches 110 according to the present invention are formed shallowly from the insulating layer 100, thereby effectively forming a fine circuit.

The circuit pattern 150 is formed on the insulating layer 100, so that one end thereof is embedded in the trenches 110 and the other end thereof is formed to protrude from the insulating layer 100. The material of the circuit pattern 150 is not limited, but typically includes copper.

The seed layer 120 is a thin metal film formed on the insulating layer 100 using electroless plating or sputtering. When the circuit pattern 150 is formed on the insulating layer 100 using plating, the seed layer may function as a lead wire. The metal of the seed layer 120 may include for example nickel or nickel alloy, such as nickel-copper alloy, nickel-chromium alloy, nickel-copper-chromium alloy, etc.

FIGS. 1B to 1E show a variety of circuit structures according to the present embodiment. The shape of the other end of the circuit pattern 150 protruding from the insulating layer 100 is the same in respective circuit structures, but the shape of one end of the circuit pattern embedded in the trenches 110 may vary depending on the shape of the trenches 110. The shape of the trenches 110 is described as above, and its description is omitted.

Method of Manufacturing PCB

FIGS. 2A˜2F, 3 to 7 are cross-sectional views sequentially showing the process of manufacturing the PCB according to the present embodiment. With reference thereto, the method of manufacturing the PCB according to the present embodiment is described below.

First, as shown in FIGS. 2A˜2F, an insulating layer 100 is prepared, and trenches 110 are processed in a negative shape on the insulating layer 100. The trenches 110 may be processed using a laser or imprinting. A variety of modifications of the trenches 110 are illustrated in FIGS. 2A˜2F, and the detailed description of the trenches 110 is the same as above and is thus omitted. In FIGS. 2E and 2F, first grooves 116 and second grooves 114, 115 are formed. These first grooves 116 and second grooves 114, 115 may be sequentially processed using a laser or imprinting. The trenches 110 are a region in which the circuit pattern 150 is embedded, and should be formed to have the same pattern as that of one end of the circuit pattern 150, and intervals between respective trenches 110 may vary depending on the shape of the circuit pattern 150.

Next, as shown in FIG. 3, a seed layer 120 is formed on the insulating layer 100 having the trenches 110. As such, the seed layer 120 may be formed at a predetermined thickness (e.g. 1 μm) or more in order to form the circuit pattern 150 using electroplating.

The seed layer 120 may be formed using electroless plating or sputtering. The electroless plating includes degreasing, soft etching, pre-catalysis, catalysis, activating, electroless plating, and antioxidation. On the other hand, the sputtering process allows gas ion particles generated by plasma to collide with a copper target, thereby forming an electroless plating layer on the insulating layer 100 and the trenches 110.

Next, as shown in FIG. 4, a resist film is applied on the seed layer 120, and openings are processed in the resist film so as to correspond to the trenches 110 thus forming a plating resist pattern 130. Specifically, the resist film is applied on the seed layer 120, and then blocked by a mask and irradiated with UV light. The mask has a pattern at a position corresponding to the circuit pattern 150 to be formed. Thereafter, the resist film is exposed to a developing solution, so that the portion cured by UV irradiation is left behind and the uncured portion is removed by the developing solution, thereby forming the plating resist pattern 130.

In order to typically form the circuit pattern 150 on the surface of the insulating layer 100, the plating resist pattern 130 is formed on the insulating layer 100, and the circuit pattern 150 is formed at a region exposed from the plating resist pattern 130. As such, the plating resist pattern 130 should be thicker than the circuit pattern 150. If the plating resist pattern 130 is formed thinner, the circuit pattern 150 may become thicker than the plating resist pattern 130 due to over-plating and thus may produce a short. However, when the plating resist pattern 130 of a predetermined height or more is ensured, a high-resolution circuit pattern 150 may not result. The circuit pattern 150 according to the present invention has one end and the other end, and the thickness of the circuit pattern 150 is defined as a sum of the thickness of the one end and a thickness of the other end. Because one end of the circuit pattern 150 is embedded in the trenches 110, even when the other end of the circuit pattern protrudes slightly from the insulating layer 100, the total thickness of the circuit pattern 150 will be ensured. In the present invention, the plating resist film used in the course of forming the circuit pattern 150 is made thin, thus achieving a high-resolution circuit pattern 150.

Next, as shown in FIG. 5, the circuit pattern 150 is formed on the trenches of the insulating layer 100. The circuit pattern 150 is formed via electroplating using the seed layer 120 as a lead wire. The electroplating layer has superior physical properties and facilitates the formation of a thick plating layer. As such, one end of the circuit pattern 150 is embedded in the trenches 110, and the other end thereof protrudes from the surface of the insulating layer 100.

Next, as shown in FIG. 6, the plating resist pattern 130 is stripped off and removed.

Next, as shown in FIG. 7, after the removal of the plating resist pattern 130, the seed layer 120 exposed from the circuit pattern 150 is removed. Upon removing the seed layer 120, flash etching for spraying an etchant may be performed.

As described hereinbefore, the present invention provides a PCB and a method of manufacturing the same. According to the present invention, a portion of a circuit pattern is embedded in an insulating layer, thus solving separation problems of the circuit pattern due to undercutting, consequently increasing the product yield.

Also, according to the present invention, the force of adhesion between the insulating layer and the circuit pattern can be enhanced, thus more stably forming a fine circuit pattern.

Also, according to the present invention, even when a plating resist is formed thin, it is possible to form the circuit pattern, resulting in a high-resolution circuit pattern.

Although the embodiments of the present invention regarding the PCB and the method of manufacturing the same have been disclosed for illustrative purposes, those skilled in the art will appreciate that a variety of different modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. A printed circuit board, comprising:
an insulating layer having a trench formed in a negative shape; and
a circuit pattern formed on the trench so that one end of the circuit pattern is embedded in the trench and the other end thereof is formed to protrude from the insulating layer.

2. The printed circuit board of claim 1, further comprising a seed layer between the insulating layer and the circuit pattern.

3. The printed circuit board of claim 1, wherein the trench has a tapered inner wall.

4. The printed circuit board of claim 1, wherein the trench comprises at least two continuously formed rectangular grooves.

5. The printed circuit board of claim 1, wherein the trench comprises at least two continuously formed inverted triangular grooves.

6. The printed circuit board of claim 1, wherein the trench comprises a first groove and at least two continuously formed rectangular second grooves on a bottom surface of the first groove.

7. The printed circuit board of claim 1, wherein the trench comprises a first groove and at least two continuously formed inverted triangular second grooves on a bottom surface of the first groove.

8. A method of manufacturing a printed circuit board, comprising:
(A) forming a trench in a negative shape on an insulating layer;
(B) applying a resist film on the insulating layer, and patterning the resist film to form an opening corresponding to the trench, thus forming a plating resist pattern;
(C) plating the insulating layer, thus forming a circuit pattern one end of which is embedded in the trench and the other end of which protrudes from a surface of the insulating layer; and
(D) removing the plating resist pattern.

9. The method of claim 8, further comprising forming a seed layer on the insulating layer, between (A) and (B).

10. The method of claim 9, further comprising (E) removing the seed layer exposed from the circuit pattern, after (D).

11. The method of claim 8, wherein (A) comprises forming a trench having a tapered inner wall on the insulating layer.

12. The method of claim 8, wherein (A) comprises forming a trench comprising at least two continuously formed rectangular grooves on the insulating layer.

13. The method of claim 8, wherein (A) comprises forming a trench comprising at least two continuously formed inverted triangular grooves on the insulating layer.

14. The method of claim 8, wherein (A) comprises forming a trench comprising a first groove and at least two continuously formed rectangular second grooves on a bottom surface of the first groove, on the insulating layer.

15. The method of claim 8, wherein (A) comprises forming a trench comprising a first groove and at least two continuously formed inverted triangular second grooves on a bottom surface of the first groove, on the insulating layer.
